(19) United States
(12) Patent Application Publication
(10) Pub. No.: US 2016/0065151 A1
(43) Pub. Date: Mar. 3, 2016

(54) AUDIO AMPLIFIER WITH RF INTERFERENCE SUPPRESSION FUNCTION

(71) Applicant: AIROHA TECHNOLOGY CORP., Hsinchu (TW)

(72) Inventors: YU-HSUAN KANG, HSINCHU (TW); HENG-CHIH LIN, HSINCHU (TW)

(21) Appl. No.: 14/602,528

(22) Filed: Jan. 22, 2015

(30) Foreign Application Priority Data
Sep. 1, 2014 (TW) 103130126

(51) Int. Cl. H03F 3/183

(52) U.S. Cl. CPC H03F 3/183; H03F 2200/03; H03F 2200/129

(57) ABSTRACT

The present invention is related to an audio amplifier with RF interference suppression function, mainly comprising at least one amplifying unit and a speaker. The amplifying unit comprises a first input end, a second input end and an output end, in which a feedback circuit is presented between the first input end and the output end. The feedback circuit is provided therein with at least one resistor and at least one capacitor, in which the resistor is situated between the first input end and the output end, while one end of the capacitor is connected to the feedback circuit. RF signals entering from the speaker may be filtered out through the provision of the resistor and the capacitor in the feedback circuit. Thereby, interference generated on the audio amplifier due to RF signals is suppressed.

### FIELD OF THE INVENTION

The present invention is related to an audio amplifier with RF interference suppression function, mainly providing at least one capacitor and/or at least one resistor in a feedback circuit, so as to filter out RF signals entering the audio amplifier.

### BACKGROUND

Referring to FIG. 1, there is shown a circuit diagram of a conventional audio amplifier. As illustrated in the figure, the audio amplifier 10 mainly comprises an amplifying unit 11, a speaker 13, a first resistor 151 and a second resistor 153, in which the amplifying unit 11 comprises a first input end 111, a second input end 113 and an output end 115. The amplifying unit 11 is connected to the speaker 13 through the output end 115, and thus, amplified audio signals may be then sent to the speaker 13.

The second resistor 153 is connected to the first input end 111 of the amplifying unit 11, and thus, audio signals may be inputted to the first input end 111 of the amplifying unit 11 through the second resistor 153. The first resistor 151 is connected at one end thereof to the first input end 111 of the amplifying unit 11, while the first resistor 151 is connected at the other end thereof to the output end 115 of the amplifying unit 11. In the practical application, various ratios of resistance of the first resistor 151 to that of the second resistor 153 may be selected, such that power of amplification of the amplifying unit 11 may meet expectations.

The audio amplifier 10 may be an earphone or Bluetooth headset, and may be used for connecting to a communication device, such as mobile phone, smart phone, tablet PC, notebook or computer. Thereby, audio signals sent by the communication device may be received by a user through the audio amplifier 10.

In general, the frequency band of RF signals received by the communication device is much higher than that of audio signals. For instance. the frequency band of RF signals received or transmitted in GSM system is approximate 900 MHz. Therefore, no interference may occur on the audio amplifier 10 due to RF signals theoretically. RF signals, however, is generally switched on and off at a constant frequency. In this case, the frequency band at which RF signals are switched on and off may fall within the frequency range of audio signals. For instance, the frequency band at which RF signals is switched on and off in GSM system is approximate 217 Hz. It is possible for RF signals to enter the speaker 13 from the audio amplifier 10, and therefore interfere audio signals generated by the audio amplifier 10, during the process of transmitting or receiving RF signals by the communication device to which the audio amplifier 10 is connected.

### SUMMARY OF THE INVENTION

It is one object of the present invention to provide an audio amplifier with RF interference suppression function, mainly comprising the connection between at least one amplifying unit and a speaker, and providing at least one capacitor and/or at least one resistor in a feedback circuit of the amplifying unit, so as to filter out RF signals entering the audio amplifier.

It is one object of the present invention to provide an audio amplifier with RF interference suppression function, mainly comprising at least one amplifying unit and a speaker. The amplifying unit comprises a plurality of input ends and an output end, in which the output end is connected to the speaker, and at least one capacitor and/or at least one resistor are provided in a feedback circuit between the output end and one of the input ends, so as to filter out RF signals entering the audio amplifier via the connection and matching between the capacitor and the resistor.

It is one object of the present invention to provide an audio amplifier with RF interference suppression function, mainly comprising the connection between at least one amplifying unit and a speaker. A filtering unit is provided in a feedback circuit of the amplifying unit, in which the filtering unit is capable of filtering out RF signals, without filtering out audio signals.

It is one object of the present invention to provide an audio amplifier with RF interference suppression function, in which the audio amplifier is used for connecting to a communication device, and thus, receiving audio signals sent by the communication device. In addition, RF signals received or transmitted by the communication device during the process of communication may be filtered out by a filtering unit within the audio amplifier, such that no interference may occur on the audio amplifier due to RF signals.

To achieve these and other objects of the present invention, the present invention provides an audio amplifier with RF interference suppression function, comprising: at least one amplifying unit, comprising a first input end and an output end; a feedback circuit, situated between the first input end and the output end; at least one filtering unit, provided in the feedback circuit and used for filtering out RF signals; and a speaker, connected to the output end of the amplifying unit.

Further, the present invention provides another audio amplifier with RF interference suppression function, comprising: a first amplifying unit, comprising a first input end and an output end; a first feedback circuit, situated between the first input end and the output end of the first amplifying unit; a first filtering unit, situated in the first feedback circuit and used for filtering out RF signals; a second amplifying unit, comprising a first input end and an output end; a second feedback circuit, situated between the first input end and the output end of the second amplifying unit; a second filtering unit, situated in the second feedback circuit and used for filtering out RF signals; and a speaker, connected to the output ends of the first amplifying unit and the second amplifying unit.

In one embodiment of the audio amplifier, the filtering unit comprises at least one first resistor and at least one first capacitor, the first resistor is situated in the feedback circuit, and one end of the first capacitor is connected to the feedback circuit.

In one embodiment of the audio amplifier, the filtering unit further comprises at least one inductor connected with the first capacitor in series.

In one embodiment of the audio amplifier, one end of the first capacitor is connected between the first resistor and the first input end.

In one embodiment of the audio amplifier, further comprises at least one second resistor provided in the feedback circuit, and situated between the first resistor and the first input end, while one end of the first capacitor connected between the first resistor and the second resistor.

In one embodiment of the audio amplifier, further comprises at least one second capacitor connected with the second resistor in parallel.

In one embodiment of the audio amplifier, the filtering unit comprises at least one inductor and at least one first capacitor, the inductor is situated in the feedback circuit, while one end of the first capacitor is connected to the feedback circuit.

In one embodiment of the audio amplifier, further comprises a capacitor situated between the output end and the speaker.

In one embodiment of the audio amplifier, the amplifying unit further comprises a second input end.

In one embodiment of the audio amplifier, the first filtering unit comprises at least one first resistor and at least one first capacitor, the first resistor situated in the first feedback circuit, while one end of the first capacitor connected to the first feedback circuit. The second filtering unit comprises at least one second resistor and at least one second capacitor, the second resistor situated in the second feedback circuit, while one end of the second capacitor connected to the second feedback circuit.

In one embodiment of the audio amplifier, one end of the first capacitor is situated between the first input end of the first amplifying unit and the first resistor, while one end of the second capacitor is situated between the first input end of the second amplifying unit and the second resistor.

In one embodiment of the audio amplifier, the first resistors are multiple, and one end of the first capacitor is connected between adjacent the first resistors, while the second resistors are also multiple, and one end of the second capacitor is connected between adjacent the second resistors.

### BRIEF DESCRIPTION OF DRAWINGS

FIG. 1 is a circuit diagram of a conventional audio amplifier;

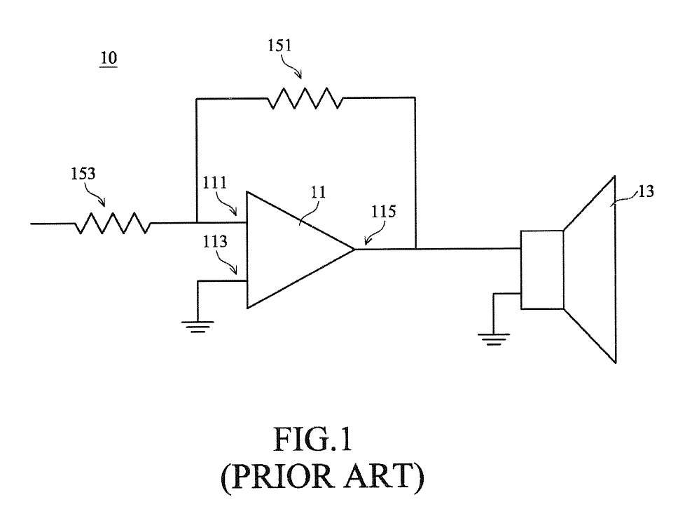

FIG. 2 is a circuit diagram of an audio amplifier with RF interference suppression function according to one embodiment of the present invention;

FIG. 3 is a circuit diagram of an audio amplifier with RF interference suppression function according to a further embodiment of the present invention;

FIG. 4 is a circuit diagram of an audio amplifier with RF interference suppression function according to a further embodiment of the present invention;

FIG. 5 is a circuit diagram of an audio amplifier with RF interference suppression function according to a further embodiment of the present invention;

FIG. 6 is a circuit diagram of an audio amplifier with RF interference suppression function according to a further embodiment of the present invention;

FIG. 7 is a circuit diagram of an audio amplifier with RF interference suppression function according to a further embodiment of the present invention;

FIG. 8 is a circuit diagram of an audio amplifier with RF interference suppression function according to a further embodiment of the present invention;

FIG. 9 is a circuit diagram of an audio amplifier with RF interference suppression function according to a further embodiment of the present invention;

FIG. 10 is a circuit diagram of an audio amplifier with RF interference suppression function according to a further embodiment of the present invention;

FIG. 11 is a circuit diagram of an audio amplifier with RF interference suppression function according to a further embodiment of the present invention;

FIG. 12 is a circuit diagram of an audio amplifier with RF interference suppression function according to a further embodiment of the present invention;

FIG. 13 is a circuit diagram of an audio amplifier with RF interference suppression function according to a further embodiment of the present invention;

FIG. 14 is a circuit diagram of an audio amplifier with RF interference suppression function according to a further embodiment of the present invention; and

FIG. 15 is a circuit diagram of an audio amplifier with RF interference suppression function according to a further embodiment of the present invention.

Although the embodiments of the present invention are illustrated in the figures by way of example, and described in detail in the text, various modifications and alternatives are still allowed. The figures of the present invention may be not drawn to scale. The figures and detailed description therefor may be only specific disclosure, and not used for limiting the present invention. In contrast, modifications, equivalent components, and substitutions on the basis of spirits and scopes of claims are all covered by the present invention.

### DETAILED DESCRIPTION

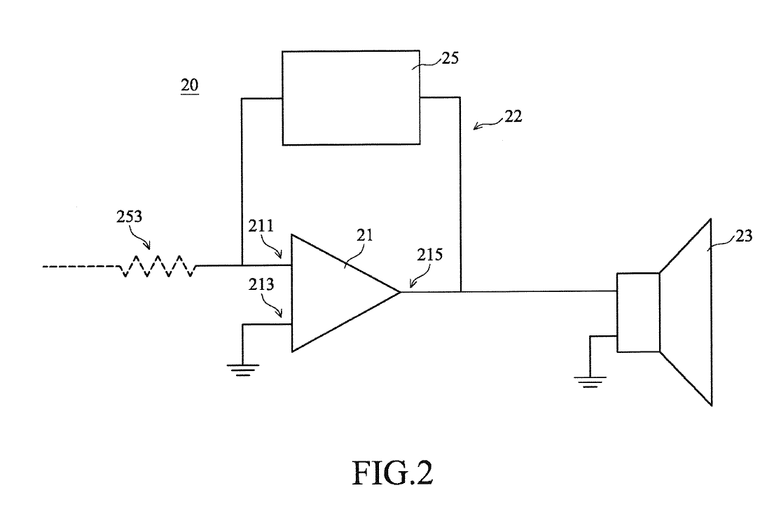

Referring to FIG. 2. there is shown a circuit diagram of an audio amplifier with RF interference suppression function according to one embodiment of the present invention. The audio amplifier with RF interference suppression function 20 described in the present invention comprises an amplifying unit 21 and a speaker 23, in which the amplifying unit 21 comprises a first input end 211, a second input end 213 and an output end 215, while the output end 215 of the amplifying unit 21 is connected to the speaker 23, and the amplified audio signals are then sent to the speaker 23.

In one embodiment of the present invention, the first input end 211 of the amplifying unit 21 is connected to a resistor 253, and the audio signals to be amplified are inputted to the first input end 211 of the amplifying unit 21 through the resistor 253. In addition, the first input end 211 of the amplifying unit 21 is electrically connected to the output end 215, and a feedback circuit 22 is then formed between the first input end 211 and the output end 215. For the present invention, the resistor 253 is not a necessary component, and the resistor 253 is then shown in FIGS. 2 to 9 in dashed line. In other words, the resistor 253 may be not required to be provided at the first input end 211 of the amplifying unit 21.

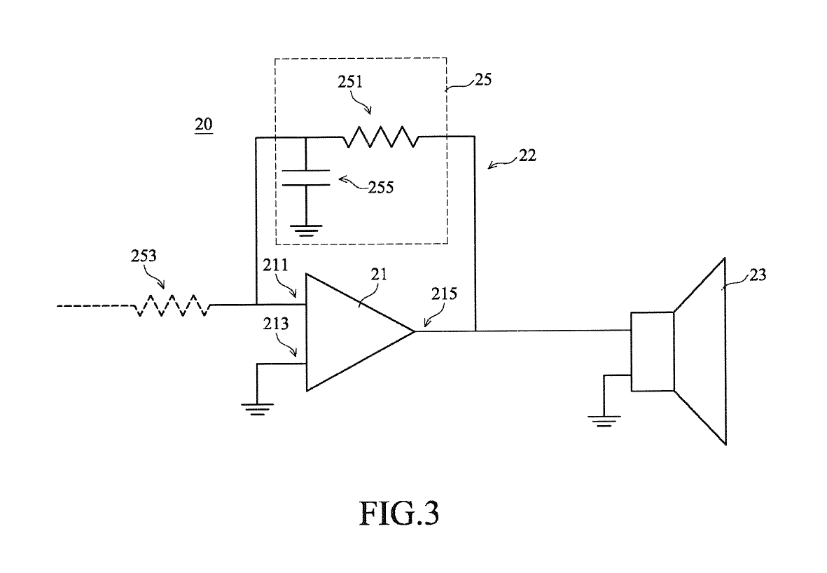

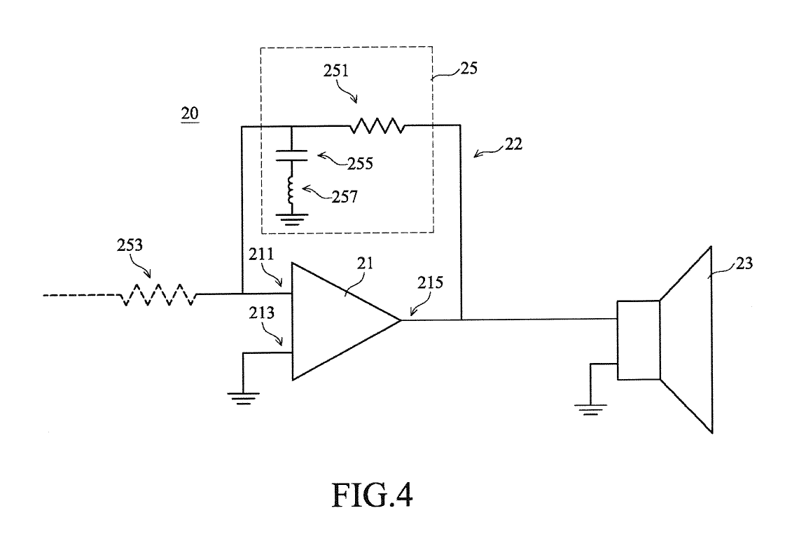

In the embodiment of the present invention, a filtering unit 25 may be provided in the feedback circuit 22, in which the filtering unit 25 is situated between the first input end 211 and the output end 215, while may be used for filtering out the frequency band of RF signals, without filtering out the audio signals, allowing the audio signals passing therethrough. In one embodiment of the present invention, as illustrated in FIG. 3, the filtering unit 25 may comprise at least one first resistor 251 and at least one first capacitor 255. In this case, the first resistor 251 is situated in the feedback circuit 22, and one end of the first capacitor 255 is connected to the feedback circuit 22. For example two ends of the first resistor 251 are respectively electrically connected to the first input end 211 and the output end 215. One end of the first capacitor 255 is connected between the first resistor 251 and the first input end 211, and the other end is grounded. In another embodiment of the present invention, as illustrated in FIG. 4, the filtering unit 25 comprises at least one first resistor 251, at least one Oct capacitor 255 and at least one inductor 257. In this case, the first resistor 251 is situated in the feedback circuit 22, while the first capacitor 255 and the inductor 257 connected in series are connected at one end thereof to the feedback circuit 22, with the other end being grounded.

For the convenience of explanation, one first resistor 251, one resistor 253 and one first capacitor 255 are primarily illustrated in FIG. 3 of the present invention. In the practical application, however, the number of first resistor 251, resistor 253 and first capacitor 255 may be also multiple. For instance, a plurality of the first resistors 251 connected in series may be provided in the feedback circuit 22, and the connection between each two adjacent first resistors 251 is connected to one end of the first capacitor 255.

The power of amplification of the amplifying unit 21 may be affected by the ratio of resistance of the first resistor 251 to that of the resistor 253, and thus, the first resistor 251 and the resistor 253 with appropriate resistance may be selected in accordance with the requirement of the audio amplifier 20. In different embodiments, of course, the first resistor 251 and/or the resistor 253 may be also variable resistors, and power of amplification of the amplifying unit 21 may be adjusted through the adjustment of resistance of the first resistor 251 and/or the resistor 253.

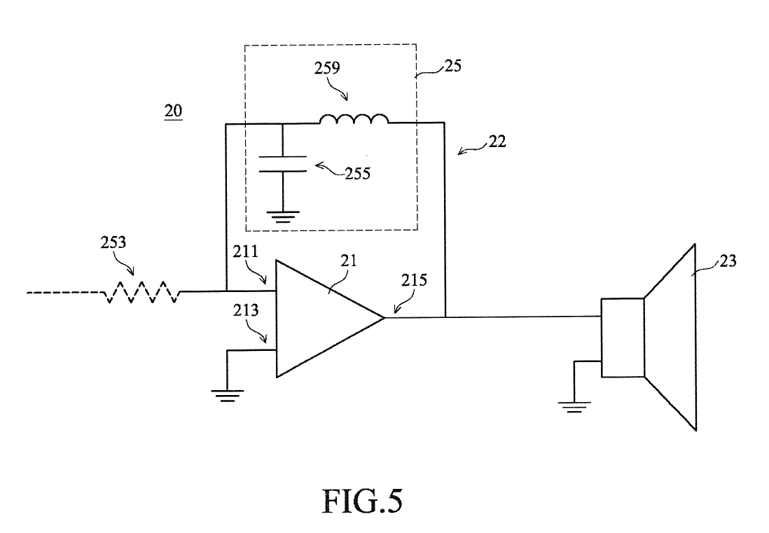

In one embodiment of the present invention, as illustrated in FIG. 5, the filtering unit 25 may comprise at least one inductor 259 and at least one first capacitor 255. In this case, the inductor 259 is situated in the feedback circuit 22, and one end of the first capacitor 255 is connected to the feedback circuit 22. For example, two ends of the inductor 259 are electrically connected to the first input end 211 and the output end 215, respectively. One end of the first capacitor 255 is connected between the inductor 259 and the first input end 211, and the other end is grounded.

As known from the above-mentioned embodiment of the present invention, the filtering unit 25 is primarily provided in the feedback circuit 22 of the audio amplifier 20 in the present invention, in which only the feature of filtering out a part of frequency band of RF signals along with passing the audio signals therethrough should be provided in the filtering unit 25. Therefore, the filtering unit 25 may be formed in other ways by those skilled in this art, and the structure of the filtering unit 25 is not limited to the disclosure described in above FIGS. 3 to 5. In the practical application, the structure of the filtering unit 25 may be designed or adjusted in accordance with the frequency band of RF signals, possibly generated, transmitted or received by electronic products using the audio amplifier 20, in such a way that RF signals at specific frequency band may be filtered out by the filtering unit 25.

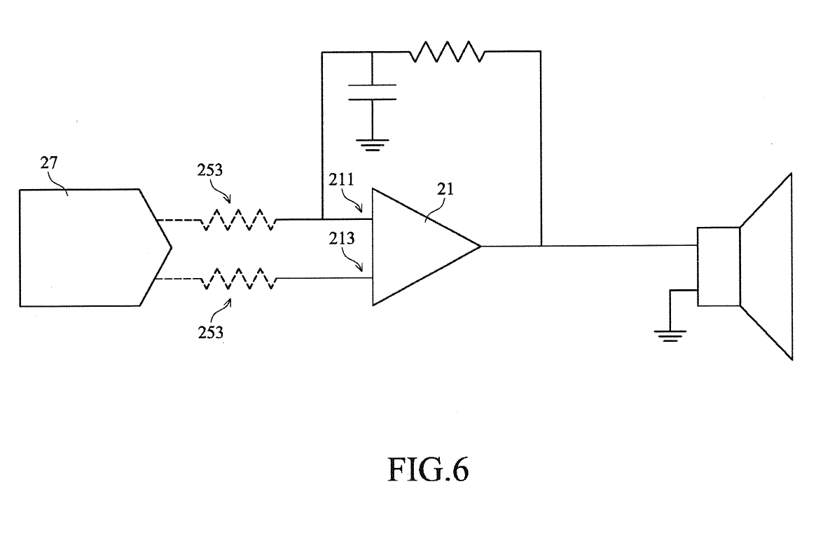

In the embodiments described in FIGS. 2 to 5 of the present invention, the audio signals may be inputted to the first input end 211 of the amplifying unit 21 through the resistor 253 or directly, while the second input end 213 of the amplifying unit 21 is connected to the ground. In different embodiments, however, the first input end 211 and the second input end 213 of the amplifying unit 21 may be also connected to a digital-to-analog converting unit (DAC) 27, as illustrated in FIG. 6. For instance, the first input end 211 and the second input end 213 are both connected to the digital-to-analog converting unit (DAC) 27 through each of resistors 253, respectively.

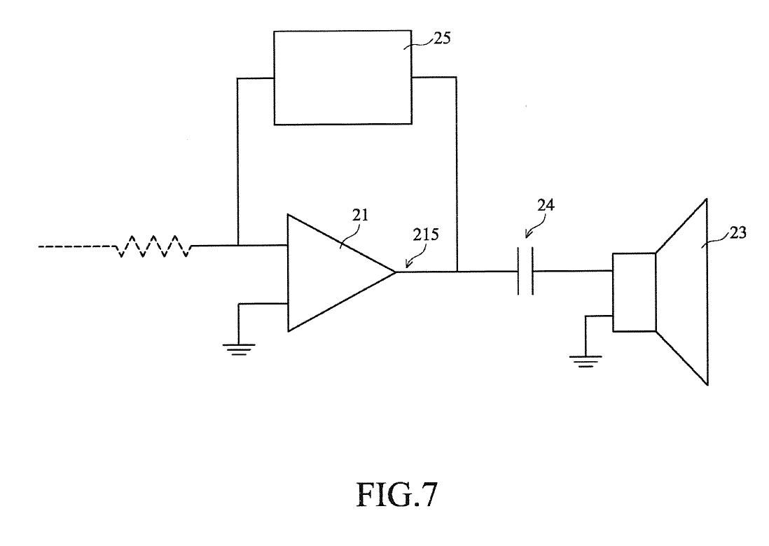

In one embodiment of the present invention, a capacitor 24 may be also added between the output end 215 of the amplifying unit 21 and the speaker 23, as illustrated in FIG. 7.

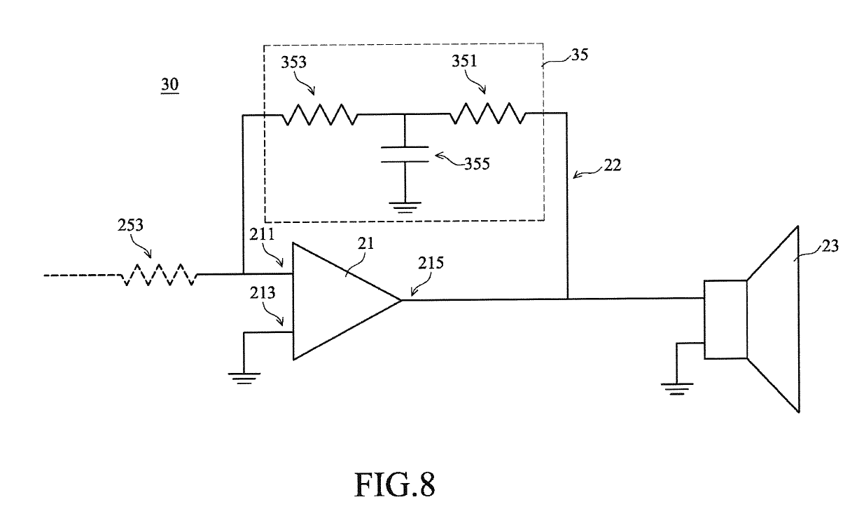

Referring to FIG. 8, there is shown a circuit diagram of an audio amplifier with RF interference suppression function according to a further embodiment of the present invention. The audio amplifier 30 described in the present invention comprises an amplifying unit 21 and a speaker 23, in which the amplifying unit 21 comprises a first input end 211, a second input end 213 and an output end 215, while the output end 215 of the amplifying unit 21 is connected to the speaker 23, and the amplified audio signals are then sent to the speaker 23.

The first input end 211 of the amplifying unit 21 is connected to a resistor 253, and the audio signals to be amplified are inputted to the first input end 211 of the amplifying unit 21 through the resistor 253. In addition, the first input end 211 of the amplifying unit 21 is electrically connected to the output end 215, and a feedback circuit 22 is then formed between the first input end 211 and the output end 215.

In the embodiment of the present invention, a filtering unit 35 may be provided in the feedback circuit 22. The filtering unit 35 may comprise at least one first resistor 351, at least one first capacitor 355 and at least one second resistor 353. In this case, the first resistor 351 and the second resistor 353 are situated in the feedback circuit 22. For instance, the first resistor 351 and the second resistor 353 are connected in series, and the first resistor 351 is electrically connected at one end thereof to the output end 215 and the speaker 23, while the second resistor 353 is electrically connected at one end thereof to the first input end 211. In other words, the second resistor 353 may be situated between the first input end 211 and the first resistor 351. The first capacitor 355 is connected at one end thereof to the feedback circuit 22. For example, one end of the first capacitor 355 is connected between the first resistor 351 and the second resistor 353, and the other end of the first capacitor 355 is grounded.

For the ease of explanation, one resistor 253, one first resistor 351, one second resistor 353 and one first capacitor 355 are primarily illustrated in FIG. 8 of the present invention. In the practical application, however, the number of resistor 253, first resistor 351, second resistor 353 and first capacitor 355 may be also multiple. For instance, a plurality of the first resistors 351 connected in series may be provided in the feedback circuit 22, and the connection between each two adjacent first resistors 351 is connected to one end of the first capacitor 355.

The resistor 253, first resistor 351, first capacitor 355, second resistor 353 and/or amplifying unit 21 described in the embodiments of the present invention may be integrated into one and the same chip. However, in different embodiments, it is also possible to only integrate the first resistor 351, second resistor 353 and/or amplifying unit 21 into one and the same chip, with the first capacitor 355 and the resistor 253 being provided as elements provided outside of the chip. For instance, the first capacitor 355 and the resistor 253 may be provided on a circuit board (not shown).

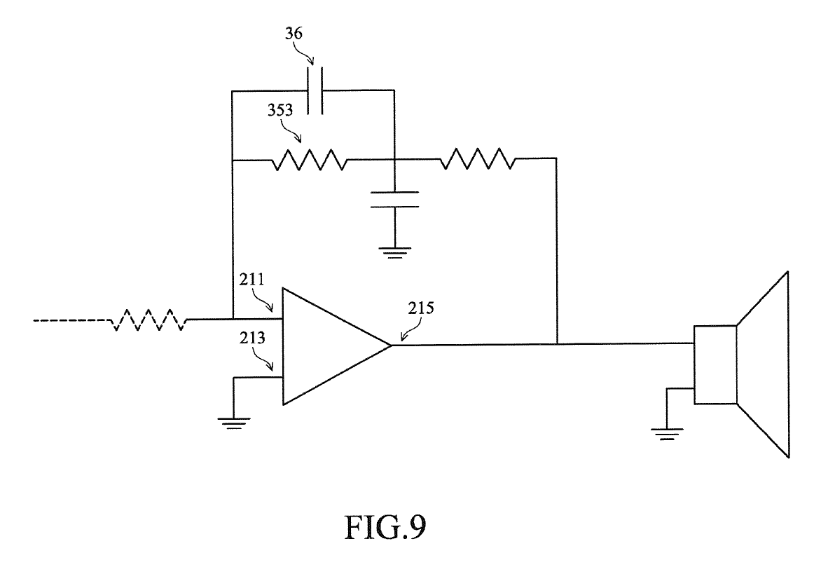

In another embodiment of the present invention, as illustrated in FIG. 9, a second capacitor 36 and the second resistor 353 may be connected in parallel. The noise in audio signals may be filtered out due to the provision of second capacitor 36, so as to enhance the quality of audio signals outputted from the audio amplifier 30.

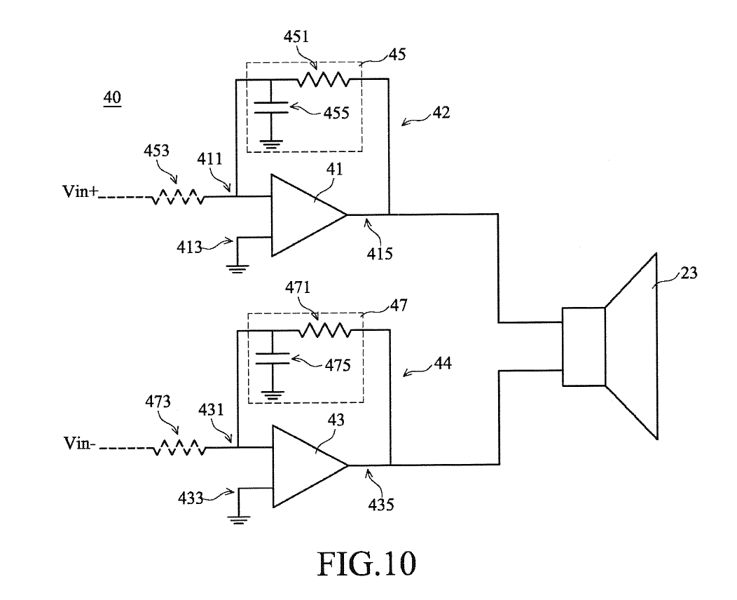

Referring to FIG. 10, there is shown a circuit diagram of an audio amplifier with RF interference suppression function according to a further embodiment of the present invention. The audio amplifier 40 described in the present invention comprises a first amplifying unit 41, a second amplifying unit 43 and a speaker 23. The first amplifying unit 41 comprises a first input end 411, a second input end 413 and an output end 415. while the second amplifying unit 43 comprises a first input end 431, a second input end 433 and an output end 435. In this case, the output end 415 of the first amplifying unit 41 and the output end 435 of the second amplifying unit 43 may be connected to the speaker 23, and the amplified audio signals may be thus delivered to the speaker 23.

The first input end 411 of the first amplifying unit 41 is connected to a resistor 453, and thus, the audio signals to be amplified may be inputted to the first input end 411 of the first amplifying unit 41 through the resistor 453. In addition, the first input end 411 of the first amplifying unit 41 is electrically connected to the output end 415. and a first feedback circuit 42 is then formed between the first input end 411 and the output end 415.

In the embodiment of the present invention, a first filtering unit 45 is provided in the first feedback circuit 42 of the first amplifying unit 41. In this case, the first filtering unit 45 may be used for filtering out the frequency band of RF signals, without filtering out the audio signals. allowing the audio signals passing therethrough. In one embodiment of the present invention, the first filtering unit 45 may comprise at least one first resistor 451 and at least one first capacitor 455. In this case, the first resistor 451 is situated in the first feedback circuit 42, and one of the first capacitor 455 is connected to the first feedback circuit 42. For example. two ends of the first resistor 451 are electrically connected to the first input end 411 and the output end 415, respectively. One end of the first capacitor 455 is connected between the first input end 411 and the first resistor 451, and the other end is grounded.

The connection of the second amplifying unit 43 is similar to that of the first amplifying unit 41. In this case, the first input end 431 of the second amplifying unit 43 is connected to a resistor 473, and thus, the audio signals to be amplified may be inputted to the first input end 431 of the second amplifying unit 43 through the resistor 473. In addition, the first input end 431 of the second amplifying unit 43 is electrically connected to the output end 435, and a second feedback circuit 44 is then formed between the first input end 431 and the output end 435. A second filtering unit 47 is provided in the second feedback circuit 44 of the second amplifying unit 43. In this case, the second filtering unit 47 may be used for filtering out the frequency band of RF signals, without filtering out the audio signals, allowing the audio signals passing therethrough. In one embodiment of the present invention, the second filtering unit 47 may comprise at least one second resistor 471 and at least one second capacitor 475. In this case, the second resistor 471 is situated in the second feedback circuit 44, and one end of the second capacitor 475 is connected to the second feedback circuit 44. For example, two ends of the second resistor 471 are electrically connected to the first input end 431 and the output end 435, respectively. One end of the second capacitor 475 is connected between the first input end 431 and the fourth resistor 473, and the other end is grounded.

In one embodiment of the present invention, the first input end 411 of the first amplifying unit 41 and the first input end 431 of the second amplifying unit 43 may be connected to the digital-to-analog converting unit (DAC) 27 as illustrated in FIG. 6, and a differential signal is inputted to the first amplifying unit 41 and the second amplifying unit 43. For instance. the positive input signal (Vin+) is received by the first input end 411 of the first amplifying unit 41, while the negative input signal (Vin−) is received by the first input end 431 of the second amplifying unit 43, in which the positive input signal (Vin+) and the negative signal (Vin−) may be the differential signal. In addition, the second input end 413 of the first amplifying unit 41 and the second input end 433 of the second amplifying unit 43 are both connected to the ground.

For the present invention, the resistor 453/473 is nota necessary component, and the resistor 453/473 is then shown in FIG. 10 in dashed line. In other words, the resistor 453/473 may be not required to be provided at the first input end 411/431 of the first amplifying unit 41 and the second amplifying unit 43.

In another embodiment of the present invention each of the first amplifying unit 41 and the second amplifying unit 43 may comprise only one first input end 411/431, without providing the second input end 413/433.

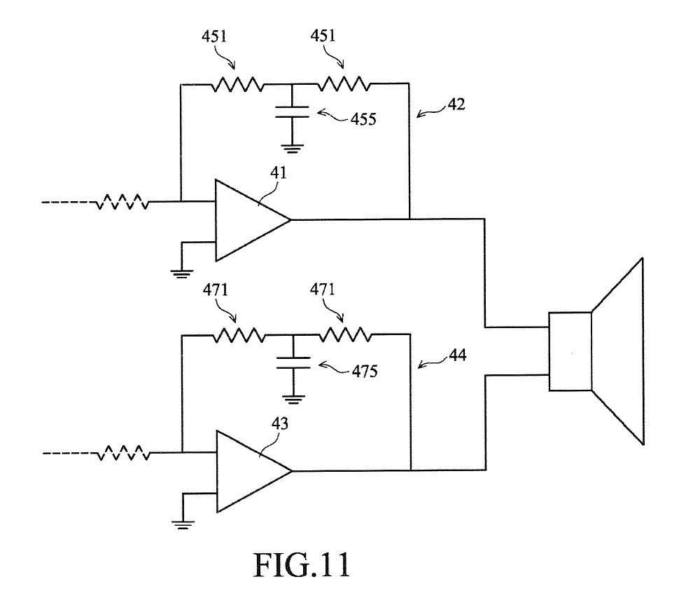

For the convenience of explanation, one First resistor 451, one resistor 453, one first capacitor 455, one second resistor 471, one resistor 473 and one second capacitor 475 are primarily illustrated in FIG. 10 of the present invention. In the practical application, however, the number of first resistor 451, resistor 453, first capacitor 455, second resistor 471, resistor 473 and second capacitor 475 may be also multiple. As illustrated in FIG. 11, for instance, a plurality of the first resistors 451 connected in series may be provided in the first feedback circuit 42, and the connection between each two adjacent resistors 451 is connected to one end of the first capacitor 455, while a plurality of the second resistors 471 connected in series may be also provided in the second feedback circuit 44, and the connection between each two adjacent second resistors 471 is connected to one end of the second capacitor 475.

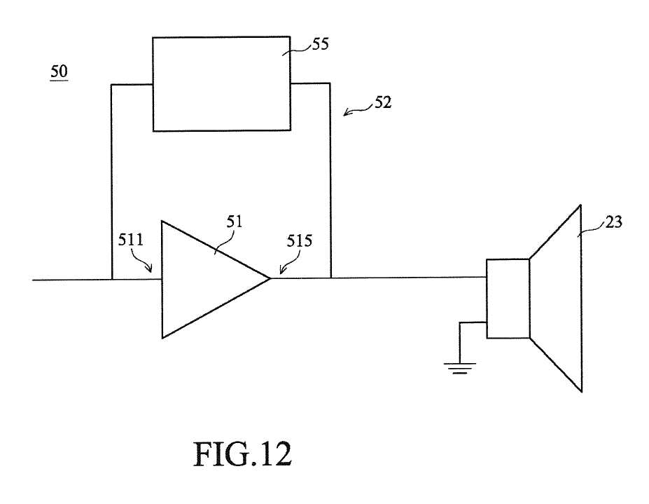

Referring to FIG. 12, there is shown a circuit diagram of an audio amplifier with RF interference suppression function according to one embodiment of the present invention. The audio amplifier with RF interference suppression function 50 described in the present invention comprises an amplifying unit 51 and a speaker 23, in which the amplifying unit 51 comprises a first input end 511 and an output end 515, while the output end 515 of the amplifying unit 51 is connected to the speaker 23, and the amplified audio signals are then sent to the speaker 23.

The first input end 511 of the amplifying unit 51 is electrically connected to the output end 515, and a feedback circuit 52 is then formed between the first input end 511 and the output end 515, as well as the audio signals to be amplified are inputted to the first input end 511 of the amplifying unit 51.

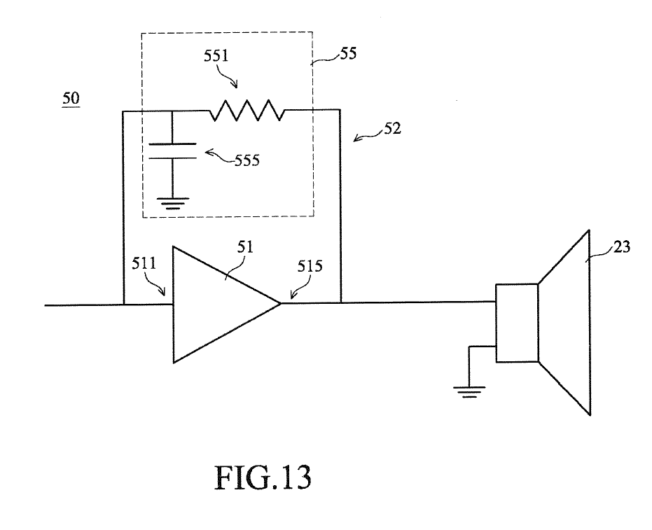

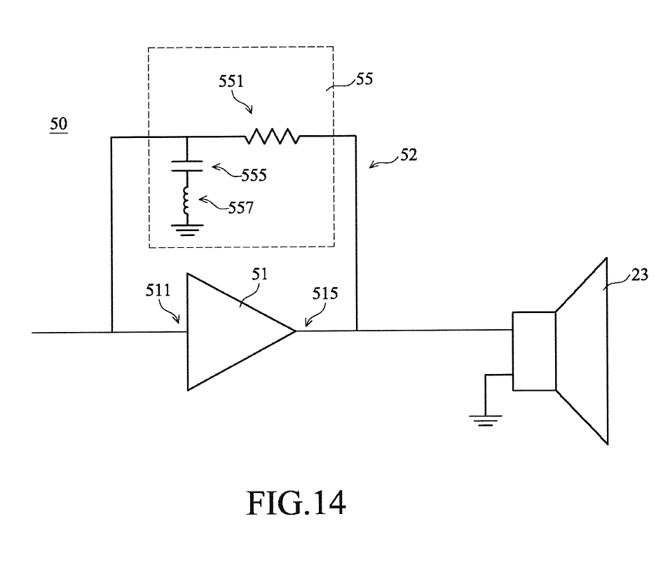

In the embodiment of the present invention, a filtering unit 55 may be provided in the feedback circuit 52, in which the filtering unit 55 is situated between the first input end 511 and the output end 515. while may be used for filtering out the frequency band of RF signals, without filtering out the audio signals, allowing the audio signals passing therethrough. In one embodiment of the present invention, as illustrated in FIG. 13, the filtering unit 55 may comprise at least one first resistor 551 and at least one first capacitor 555. In this case, the first resistor 551 is situated in the feedback circuit 52, and one end of the capacitor 555 is connected to the feedback circuit 52. For example, two ends of the first resistor 551 are electrically connected to the first input end 511 and the output end 515, respectively. The one end of the first capacitor 555 is connected between the first resistor 551 and the first input end 511, and the other end is grounded. In another embodiment of the present invention, as illustrated in FIG. 14, the filtering unit 55 comprises at least one first resistor 551, at least one capacitor 555 and at least one inductor 557. In this case, the first resistor 551 is situated in the feedback circuit 52, while the capacitor 555 and the inductor 557 connected in series are connected at one end thereof to the feedback circuit 52, with the other end being grounded.

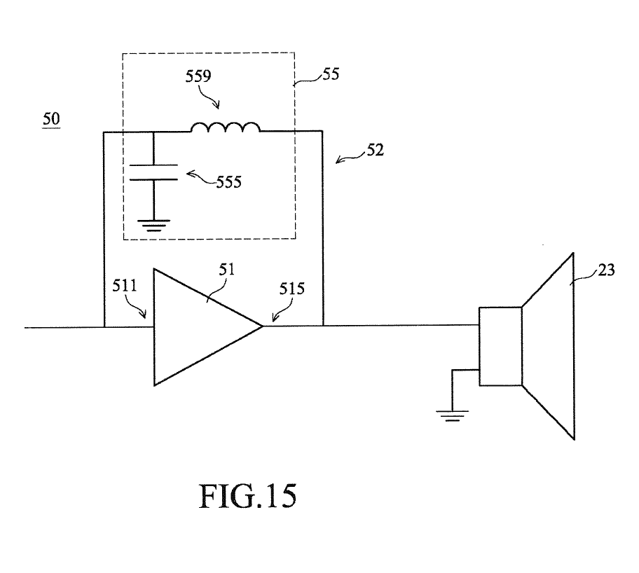

In one embodiment of the present invention, as illustrated in FIG. 15, the filtering unit 55 may comprise at least one inductor 559 and at least one first capacitor 555. In this case, the inductor 559 is situated in the feedback circuit 52, and one end of the first capacitor 555 is connected to the feedback circuit 52. For example, two ends of the inductor 559 are electrically connected to the first input end 511 and the output end 515, respectively. The one end of the first capacitor 555 is connected between the inductor 559 and the first input end 511, and the other end is grounded.

Each audio amplifier 50 illustrated in FIGS. 12 to 15 and each audio amplifier 20 illustrated in FIGS. 2 to 5 of the present invention are similar, respectively, with primary difference therebetween consisting in that each amplifying unit 21 of the audio amplifier 20 illustrated in FIGS. 2 to 5 comprises two input ends, such as the first input end 211 and the second input end 213, while each amplifying unit 51 of the audio amplifier 50 illustrated in FIGS. 12 to 15 comprises one first input end 511. Therefore, the audio amplifier 50 illustrated in FIGS. 12 to 15 of the present invention may be construed as the structure in FIGS. 6 to 11 by those skilled in this art, in which the number of input ends of the amplifying unit in FIGS. 6 to 11 is one.

The audio amplifier 20/30/40/50 described in the above embodiment of the present invention may be a device having a sounding function, such as an earphone, speaker, Bluetooth headset, hands-free receiver, and etc., and used for connecting to a communication device, such as mobile phone, smart phone, tablet PC, notebook, or computer, whereby audio signals may be sent to the audio amplifier 20/30/40/50 by the communication device. In addition, the audio amplifier 20/30/40/50 may not be interfered by RF signals transmitted or received by the communication device when the audio amplifier 20/30/40/50 is connected to the communication device, whereby sound quality of the audio amplifier 20/30/40/50 may be improved.

The connection described in the present invention is directed to direct connection or indirect connection between two or among more objects or components. For instance, one or more interconnections may be presented between two or among more objects or components.

The above disclosure is only the preferred embodiment of the present invention. and not used for limiting the scope of the present invention. All equivalent variations and modifications on the basis of shapes, structures, features and spirits described in claims of the present invention should be included in the claims of the present invention.

1. An audio amplifier with RF interference suppression function, comprising:
at least one amplifying unit, comprising a first input end and an output end;
a feedback circuit, situated between said first input end and said output end;
at least one filtering unit, provided in said feedback circuit and used for filtering out RF signals; and
a speaker, connected to said output end of said amplifying unit.

2. The audio amplifier according to claim 1, wherein said filtering unit comprises at least one first resistor and at least one first capacitor, wherein said first resistor is situated in said feedback circuit, while one end of said first capacitor is connected to said feedback circuit.

3. The audio amplifier according to claim 2, wherein said filtering unit further comprises at least one inductor connected with said first capacitor in series.

4. The audio amplifier according to claim 2, wherein one end of said First capacitor is connected between said first resistor and said first input end.

5. The audio amplifier according to claim 2, further comprising at least one second resistor provided in said feedback circuit, and situated between said first resistor and said first input end, while one end of said first capacitor connected between said first resistor and said second resistor.

6. The audio amplifier according to claim 5, further comprising at least one second capacitor connected with said second resistor in parallel.

7. The audio amplifier according to claim 1, wherein said filtering unit comprises at least one inductor and at least one first capacitor, wherein said inductor is situated in said feedback circuit, while one end of said first capacitor is connected to said feedback circuit.

8. The audio amplifier according to claim 1, further comprising a capacitor situated between said output end and said speaker.

9. The audio amplifier according to claim 1, wherein said amplifying unit further comprises a second input end.

10. An audio amplifier with RF interference suppression function, comprising:
a first amplifying unit, comprising a first input end and an output end;
a first feedback circuit, situated between said first input end and said output end of said first amplifying unit;
a first filtering unit, situated in said first feedback circuit and used for filtering out RF signals;
a second amplifying unit, comprising a first input end and an output end;
a second feedback circuit, situated between said first input end and said output end of said second amplifying unit;
a second filtering unit, situated in said second feedback circuit and used for filtering out RF signals; and
a speaker, connected to said output ends of said first amplifying unit and said second amplifying unit.

11. The audio amplifier according to claim 10, wherein said first filtering unit comprises at least one first resistor and at least one first capacitor, said first resistor situated in said first feedback circuit, while one end of said first capacitor connected to said first feedback circuit, as well as said second filtering unit comprises at least one second resistor and at least one second capacitor, said second resistor situated in said second feedback circuit, while one end of said second capacitor connected to said second feedback circuit.

12. The audio amplifier according to claim 11, wherein one end of said first capacitor is situated between said first input end of said first amplifying unit and said first resistor, while one end of said second capacitor is situated between said first input end of said second amplifying unit and said second resistor.

13. The audio amplifier according to claim 11, wherein said first resistors are multiple, and one end of said first capacitor is connected between adjacent said first resistors, while said second resistors are also multiple, and one end of said second capacitor is connected between adjacent said second resistors.
